(19) United States
(12) Patent Application Publication
(10) Pub. No.: US 2008/0009417 A1
(43) Pub. Date: Jan. 10, 2008

(54) COATING COMPOSITION, ARTICLE, AND ASSOCIATED METHOD

(75) Inventors: Victor Lienkong Lou, Niskayuna, NY (US); George Theodore Dalakos, Niskayuna, NY (US); Marc Schaepkens, Medina, OH (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: GENERAL ELECTRIC COMPANY, Schenectady, NY (US)

(21) Appl. No.: 11/560,953

(22) Filed: Nov. 17, 2006

Related U.S. Application Data
(60) Provisional application No. 60/818,590, filed on Jul. 5, 2006.

(51) Int. Cl. H01L 39/24

(52) U.S. Cl. 505/100

(57) ABSTRACT

A processing apparatus for use in a corrosive operating environment at a temperature range of 25-1500° C. is provided. The apparatus has protective coating structure that includes a glassy material. The glassy material includes at least one of yttrium, cerium, or gadolinium; and aluminum and silicon. The coating composition resists etching by a harsh environment.

### CROSS REFERENCE TO RELATED APPLICATIONS

This patent application claims benefit and priority to U.S. Provisional Pat. Application Ser. No. 60/818,590 filed on Jul. 5, 2006, the contents of which are incorporated by reference.

### BACKGROUND

1. Technical Field

The invention relates to articles and apparatuses for use in the semiconductor processing industry and other corrosive environments, and methods for making articles and apparatuses thereof. In one embodiment, the invention also relates to methods of making or using compositions for use in coating articles and apparatuses for use in the semiconductor processing industry and other corrosive environments.

2. Discussion of Related Art

The process for fabrication of electronic devices comprises a number of process steps that rely on either the controlled deposition or growth of materials or the controlled and often selective modification of previously deposited/grown materials. Exemplary processes include Chemical Vapor Deposition (CVD), Thermal Chemical Vapor Deposition (TCVD), Plasma Enhanced Chemical Vapor Deposition (PECVD), High Density Plasma Chemical Vapor Deposition (HDP CVD), Expanding Thermal Plasma Chemical Vapor Deposition (ETP CVD), Metal Organic Chemical Vapor Deposition (MOCVD), etc. In some of the processes such as CVD, one or more gaseous reactants are used inside a reactor under low pressure and high temperature conditions to form a solid insulating or conducting layer on the surface of a semiconductor wafer, which is located on a substrate (wafer) holder placed in a reactor.

The substrate holder in the CVD process could function as a heater, which typically contains at least one heating element to heat the wafer; or could function as an electrostatic chuck (ESC), which comprises at least one electrode for electro-statically clamping the wafer; or could be a heater/ESC combination, which has electrodes for both heating and clamping. A substrate holder assembly may include a susceptor for supporting a wafer, and a plurality of heaters disposed under the susceptor to heat the wafer. The semiconductor wafer is heated within a confined environment in a processing vessel at relatively high temperature and often in an atmosphere that is highly corrosive.

After a deposition of a film of predetermined thickness on the semiconductor wafer, there often is spurious deposition on other exposed surfaces inside the reactor. This spurious deposition could present problems in subsequent depositions. It is therefore periodically removed with a cleaning process, i.e. in some cases after every wafer and in other cases after a batch of wafers has been processed. Common cleaning processes in the art include atomic fluorine based cleaning, fluorocarbon plasma cleaning, sulfur hexafluoride plasma cleaning, nitrogen trifluoride plasma cleaning, and chlorine trifluoride cleaning. In the cleaning process, the reactor components, e.g., walls, windows, the substrate holder and assembly, etc., are often corroded/chemically attacked. The corrosion can be extremely aggressive on surfaces that are heated to elevated temperatures, e.g. such as the operating temperature of a typical heater which is typically in the 400-500° C. range but can be as high as the 600-1000° C. range.

Silica is sometimes used in semi-conductor wafer fabrication. Silica is susceptible to etching by halogens, and particularly susceptible at operating temperatures. The useful life of a silica component may be limited by halogen corrosion. Aluminum oxide and aluminum nitride may be relatively more resistant to halogen etching than silicon oxide, and they are used in some applications.

Currently available materials can be polycrystalline, and therefore have grain boundaries. The etch rate at the grain boundary may be different from the etch rate of the grain body. The differing etch rates may allow for particle generation or dust production that may undesirably contaminate work products.

There is still a need for articles and apparatuses suitable for semiconductor-processing environments, including those employing corrosive gases, as currently employed materials for use in articles and components such as heaters and electrostatic chucks may be lacking in one or more desired properties or characteristics.

### BRIEF DESCRIPTION

A composition according to an embodiment of the invention is provided. The composition includes a glassy material. The glassy material includes at least one of yttrium, cerium, or gadolineum; and aluminum and silicon. The composition resists etching by a harsh environment.

In one embodiment, a method includes contacting powders comprising at least one of yttrium, cerium, or gadolineum; and aluminum and silicon. The powders may be heated to form a glassy structure or glassy layer.

A heater is provided in one embodiment. The heater includes a heating element having a plurality of leads and an electrically resistive heat-generating body; and a glassy structure sealing the heating element from a proximate environment, wherein the glassy structure comprises yttrium, aluminum, and silicon, and the glassy structure resists etching in a harsh environment.

A chuck is provided in one embodiment. The chuck includes an electrode; and a glassy structure sealing the electrode from a proximate environment, wherein the glassy structure comprises yttrium, aluminum, and silicon, and the glassy structure resists etching in a harsh environment.

### BRIEF DESCRIPTION OF DRAWING FIGURES

FIG. 1 is a schematic cross-sectional view of an article comprising an embodiment of the invention.

FIG. 2 is Ternary Diagram of Yttrium-Aluminum-Silicon over which is laid temperature ranges corresponding to three sample composition according to embodiments of the invention.

FIG. 3 is a schematic cross-sectional view of an article comprising an embodiment of the invention.

FIG. 4 is a schematic cross-sectional view of an article comprising an embodiment of the invention.

FIG. 5 is a photograph of a heater comprising an embodiment of the invention.

FIG. 6 is a schematic cross-sectional view of an article comprising an embodiment of the invention.

### DETAILED DESCRIPTION

The invention includes embodiments that relate to coating compositions. The invention includes embodiments that relate to coated articles. The invention includes embodiments that relate to methods of making and using the coating compositions and/or coated articles.

Approximating language, as used herein throughout the specification and claims, may be applied to modify any quantitative representation that could permissibly vary without resulting in a change in the basic function to which it is related. Accordingly, a value modified by a term or terms, such as “about”, are not to be limited to the precise value specified. In some instances, the approximating language may correspond to the precision of an instrument for measuring the value.

As used herein, the terms “may” and “may be” indicate a possibility of an occurrence within a set of circumstances; a possession of a specified property, characteristic or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances the modified term may sometimes not be appropriate, capable, or suitable. For example, in some circumstances an event or capacity can be expected, while in other circumstances the event or capacity can not occur—this distinction is captured by the terms “may” and “may be”.

As used herein, “resist etching” or “capable of resisting etching” means being highly resistance against corrosion by corrosive gases such as fluorine and chlorine gases, and high resistance against plasma, for an etch rate in NF₃ at 600° C. of less than 100 Angstroms per min (A/min). In one embodiment, “capable of resisting etching” means an etch rate in NF₃ at 600° C. of less than 50 A/min. In yet another embodiment, “capable of resisting etching” means having an etching resistance rate to 18 weight percent feedstock gas comprising oxygen gas and at least one of carbon tetrachloride gas or nitrogen fluoride gas is less than about 10 Angstroms per minute at about 600° C.

As used herein, lanthanide includes yttrium. And, examples of yttrium are interchangeable with other lanthanides unless the species is inoperable, or context or language indicates otherwise.

Halogen Resistant YAS Glass Coating Compositions: Materials that form stable halides with high vaporization temperatures may resist etching by halogen. As the stable-halide forming material contacts the halide the reaction product forms a layer that may protect the reaction product layer from further attack. For example, fluorides of alkaline earths, Al, Ga, Y, Zr, Hf and lanthanides are non-volatile, and materials containing these elements are resistant to halogen etching. Mixed oxide silicate glasses containing aluminum oxide and yttrium oxide forms a protective layer containing yttrium, aluminum, and silicon. According to embodiments disclosed herein, such halogen resistant glasses may be referred to as YAS glasses, and may be used as a bulk solid or as a protective coating over a substrate. In alternative embodiments, additional glass former additive may be added. The amounts, ratios, and preparation of these glasses may affect the amount or degree of protection offered, or the amount of etch resistance available. These and other additives may be used to affect and control other features and attributes of the article formed therefrom. These features and attributes can include, for example, residual stress, coefficient of thermal expansion, transparency or translucency, cost, electrical and thermal properties, and the like.

With regard to the amounts of the lanthanide (L), aluminum, and silicon the ratio of each relative to each other may be controlled to affect the end-use properties and charateristics. Such end-use properties and charateristics may be associated with the use to fit the use of the particular device, needs associated with the device. The amounts and ratios may be expressed in terms of the precursor amounts used in the formation of the glassy material. In one embodiment, the amounts are expressed as a ratio of L:A:S in terms of the weight percent of the oxide precursors and may be selected from about: 40:20:40; 45:20:35; 50:20:30; 45:15:40; 45:25:30; 40:15:45; 50:25:25; and 40:25:35.

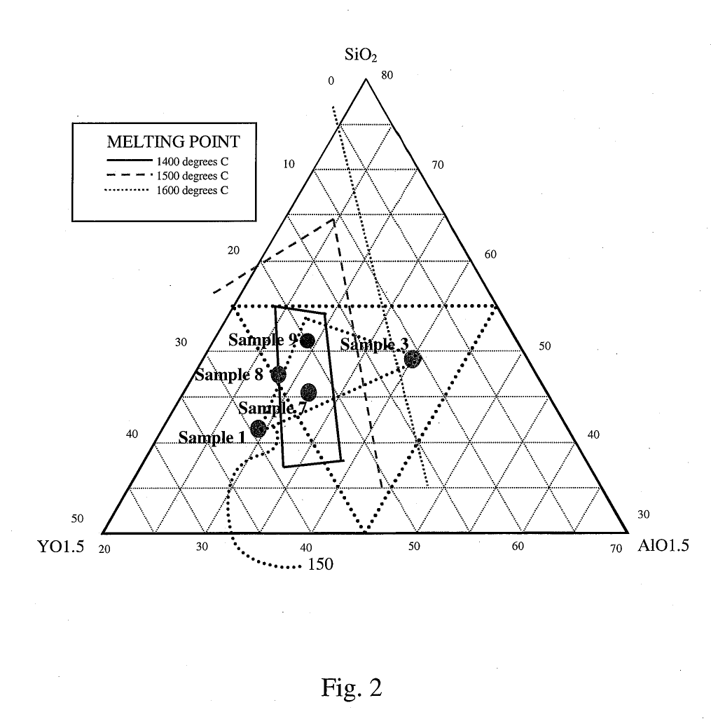

With reference to FIG. 2, a region is indicated with a dashed triangle 150. The regions indicates compositional space or molar relationships in which at least three criteria are met. The criteria may include etch resistance, glass formation, and ability to match CTE values to the CTE of a desired substrate. Depending on the end use, the compositional relationship need not remain in the triangular region in some embodiments.

A suitable ternary system may include amounts of the oxide precursors, separately, that are in a range of from about 40 weight percent to about 50 weight percent of yttrium oxide, from about 15 weight percent to about 25 weight percent of aluminum oxide, and from about 30 weight percent to about 40 weight percent silicon dixoide. In one embodiment, the yttrium oxide amount is in a range of from about 44 weight percent to about 46 weight percent, the aluminum oxide amount is in a range of from about 19 weight percent to about 21 weight percent, and the silicon dioxide amount is in a range of from about 34 weight percent to about 36 weight percent.

The proceeding is for ternary systems, for quaternary systems the ratios will differ. In a suitable quaternary system the amounts are expressed as a ratio of L:A:S:M, where L is yttrium and M is gadolinium, in terms of the weight percent of the oxide precursors and may be selected from about: 20:20:40:20; 40:20:35:5; 40:20:30:10; 45:15:20:20; 35:20:30:15; 40:15:35:10; 50:25:25; and 10:25:35:30.

In another suitable quaternary system the amounts are expressed as a ratio of L:A:S:M, where L is yttrium and M is cerium, in terms of the weight percent of the oxide precursors and may be selected from about: 20:20:40:20; 40:20:35:5; 40:20:30:10; 45:15:20:20; 35:20:30:15; 40:15:35:10; 50:25:25; and 10:25:35:30.

A suitable quaternary system may include amounts of the oxide precursors, separately, that are in a range of from about 20 weight percent to about 50 weight percent of yttrium oxide, from about 15 weight percent to about 25 weight percent of aluminum oxide, from about 30 weight percent to about 40 weight percent silicon dixoide, and at least one of cerium oxide or gadolinium oxide that is present in an amount in a range of from about 20 weight percent to about 50 weight percent of yttrium oxide. Also included are formulations for more than four-component glass materials.

Suitable additives may be used as glass formers and/or sintering aids. Suitable glass formers may include, for example, boron, phosphorus, or germanium. Other additives may include phophorus and/or boron. In one embodiment, the coating composition is a ternary system, e.g., YAS, GdAlSi, or CeAlSi. In one embodiment, the coating composition is a quaternary system, e.g., Yittrium-Aluminum-Silicon-M, where M is one of the glass formers. In one embodiment, the ternary YAS system comprises 10-30 mol. % Y, Gd, or Ce; 25 to 25 mol. % Al; and 40 to 50 mol % Si. In one embodiment, the quaternary YAS-M system comprises 10-30 mol. % Al; 25 to 25 mol. % Al; 40 to 50 mol % Si, and 1 to 15 mol % of at least a glass former M.

During manufacture, high purity fused silica may be made by melting sand at high temperatures in a furnace. A mixed oxide silica glass can be made by adding halogen-resistant materials to the starting raw material. In one embodiment, a mixed oxide glass containing aluminum oxide added to silica. In one embodiment, a mixed oxide glass containing aluminum oxide, lanthanide oxide and silica. In one embodiment, a mixed oxide glass containing aluminum oxide, yttrium oxide and silica.

In the presence of fluorine, a mixed oxide silica initially reacts and depletes surface silica. As the concentration of the fluorine resistant additive builds up on the surface, the reaction slows down and ultimately stops. The reaction product is a sintered oxide ceramic resistant to halogen, and particularly resistant to fluorine. Such oxides can be ranked in terms of the fluoride boiling points: alkaline-earths fluorides (about 2100 degrees Celsius), lanthanide fluorides (about 2100 degrees Celsius), yttrium fluoride (about 1500 degrees Celsius), aluminum fluoride (about 1100 degrees Celsius).

Lanthanide oxides and yttrium oxide have relatively greater resistance than aluminum oxide. For transparent ceramics, the oxide crystal structure may be isotropic. For example, isotropic oxide crystal structure include cubic oxides such as yttrium oxide and Y—Al garnet. Ceramic and glass articles can be made by sintering or by hot pressing a powder, for example. Halogen-resistant glasses and oxides can be used as solid materials, thick coating layers, or as thin coatings on supportive existing parts by sputtering or by chemical vapor deposition (CVD).

In terms of fluorine-resistance, yttrium and lanthanide based materials perform relatively better than aluminum-based materials. YAS coatings can be made transparent for window applications. The composition of a YAS glass can be tailored to a specific fluorine condition, glass transition temperature, thermal expansion coefficient and optical transmittance.

Applications for Wafer Processing Apparatus Comprising YAS Glass Compositions: In some embodiments, the coating may be amorphous, crystalline, or engineered to be a mixture of both amorphous and crystalline phases. The coating may be used to coat articles such as, for example, electrostatic chucks; heater elements during the manufacture of integrated circuits, semiconductors, silicon wafers, chemical compound semiconductor wafers, or liquid crystalline display devices and their glass substrates; chemical polishing chambers; or the like.

The YAS glass composition besides being used as a coating layer for an apparatus in a semiconductor processing chamber, can also fabricated into the final parts used in wafer fabrication equipments such as a window.

Properties of Wafer Processing Apparatus Comprising YAS Glass Compositions: In one embodiment, the YAS glass composition is used to coat or deposit onto a surface of a heater/ESC substrate for use in a wafer processing apparatus. The compositions when use in a harsh semiconductor processing environment, may have one or more controllable property or characteristic. The harsh environment can include halogens and/or oxidants at elevated temperatures. Suitable halogens can include one or more of chlorine, florine, bromine, and gaseous iodine. In one embodiment, the halogen is florine. The harsh environment may be a plasma. Such a harsh environment may contain ammonia or hydrogen; and, may be at an elevated temperature.

The harsh environment may be a corrosive environment, and may include one or more etchants, such as halogen-containing etchants. The etchants may include, for example, nitrogen trifluoride (NF₃) or carbon tetrafluoride (CF₄). Such a harsh environment may be associated with one or more of an environment comprising halogen, plasma etching, reactive ion etching, plasma cleaning, or gas cleaning. Examples of working environments may include halogen-based plasmas, halogen-based radicals generated from a remote plasma source, halogen-based species decomposed by heating, halogen-based gases, oxygen plasmas, oxygen-based plasmas, or the like. Examples of halogen-based plasma include a nitrogen trifluoride (NF₃) plasma, or fluorinated hydrocarbon plasma (e.g. carbon tetrafluoride (CF₄)), and may be used either alone or in combination with oxygen. The working environment may be a reactive ion etching environment.

Temperature ranges can be greater than 100 degrees Celsius. In one embodiment, the working or operational temperatures may be in a range of from about 25 degrees Celsius to about 600 degrees Celsius, from about 500 degrees Celsius to about 750 degrees Celsius, from about 750 degrees Celsius to about 800 degrees Celsius, from about 800 degrees Celsius to about 850 degrees Celsius, from about 850 degrees Celsius to about 900 degrees Celsius, from about 900 degrees Celsius to about 1000 degrees Celsius, from about 1000 degrees Celsius to about 1100 degrees Celsius, from about 1100 degrees Celsius to about 1200 degrees Celsius, from about 1200 degrees Celsius to about 1100 degrees Celsius, from about 1100 degrees Celsius to about 1400 degrees Celsius, from about 1400 degrees Celsius to about 1500 degrees Celsius, or greater than about 1500 degrees Celsius. The working or operational temperature may be achieved by a slow ramp or a fast ramp, the cool down can be slow or may be a quick quench, and there may be multiple heat cycles during use depending on the end-use application.

In one embodiment, the coating may have an etch rate of less than 100 Angstroms per minute, in a range of from about 100 Angstroms per minute to about 75 Angstroms per minute, from about 75 Angstroms per minute to about 50 Angstroms per minute, from about 50 Angstroms per minute to about 25 Angstroms per minute, from about 25 Angstroms per minute to about 15 Angstroms per minute, from about 15 Angstroms per minute to about 10 Angstroms per minute, from about 10 Angstroms per minute to about 5 Angstroms per minute, from about 5 Angstroms per minute to about 2 Angstroms per minute, from about 2 Angstroms per minute to about 1 Angstrom per minute, from about 1 Angstrom per minute to about 0.5 Angstroms per minute, from about 0.5 Angstrom per minute to about 0.1 Angstroms per minute or less than about 0.1 Angstroms per minute. In one embodiment, at a temperature that is greater than room temperature the rate of etching may be less than about 10 Angstroms/minute.

In one embodiment, the coating may have a residual stress value that is greater than or equal to about 10 megaPascal (MPa). In another embodiment, the residual stress may be greater than about 100 MPa (compressive) or greater than about 200 MPa (compressive). The coating may have a mechanical strength at temperature in a range of from about room temperature and up to more than 1000 degrees Celsius that is characterized by a bending strength or a fracture toughness. The bending strength may be at least 1100 MPa at room temperature and at least 850 MPa at 1000 degrees Celsius. The fracture toughness (KIC) may be greater than 6.5 MPa·m² at room temperature and greater than about 5 MPa·m² at 1000 degrees Celsius.

When applied to a substrate, the coating structure according to one embodiment of the invention may increase the life cycle of the article. The increase may be by a period greater than about 100 hours relative to an uncoated article. In one embodiment, the coating structure may increase the life cycle of the article by a time period in a range of from up to about 500 hours to about 1000 hours, from about 1000 hours to about 1500 hours, from about 1500 hours to about 2000 hours, or greater than about 2000 hours of service life. Service life may include the actual working life.

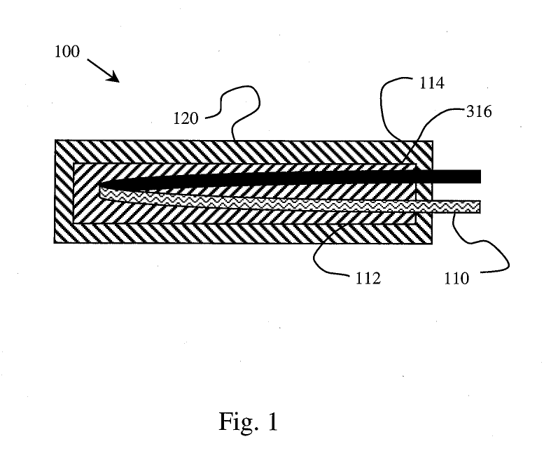

Wafer Processing Apparatus—heaters and chucks having YAS coatings: With reference to FIG. 1, an article 100 comprising a YAS coating of the invention is shown. The article may be used as a heater in a wafer processing apparatus or in semiconductor manufacture. A heating element 110 extends through a substrate 112. A YAS glass coating 114 encapsulates the substrate, covers a surface 316 of the substrate at an interface, and is adhered thereto by at least one of chemical bonding or mechanical bonding. An outward facing surface 120 of the coating is configured for exposure to a harsh environment during use.

The thickness of the outer coating may be selected with reference to the end-use application. In one embodiment, the outer coating may be thin enough to provide desired thermal contact between the substrate and a workpiece that may be in contact with the outer coating, and thick enough to provide good life span for the coating. In some embodiments, the coating may have a thickness greater than about 10 Angstroms. In one embodiment, the thickness may be in a range of from up to about 1 micrometer to about 5 micrometers, from about 5 micrometers to about 10 micrometers, from about 10 micrometers to about 50 micrometers, from about 50 micrometers to about 75 micrometers, or the thickness may be greater than about 75 micrometers.

In one embodiment, at least one electrode is embedded in or disposed on or under the base substrate 112. The electrode is selected from a resistive heating electrode, a plasma-generating electrode, an electrostatic chuck electrode, and an electron-beam electrode. In one embodiment, the electrode functions as an electrically resistive heater, with a heating element defining a path through the body of the substrate that can be serpentine, a spiral, or a helix. Suitable materials for use in forming the heating element include one or more of molybdenum, tungsten, or ruthenium. In one embodiment, the heating element includes graphite.

A suitable substrate may include one or more of a metal nitride, a metal carbide, a metal boride, or a metal oxide. In one embodiment, the substrate comprises one of graphite; refractory metals, transition metals, rare earth metals and alloys thereof; a sintered material including at least one of oxide, nitride, carbide, carbonitride or oxynitride of elements selected from a group consisting of B, Al, Si, Ga, Y, refractory hard metals, transition metals; oxide, oxynitride of aluminum; and combinations thereof. In yet another embodiment, the base substrate comprises high thermal stability zirconium phosphate having an NZP structure of NaZr₂ (PO₄)₃; refractory hard metals; transition metals; oxide, oxynitride of aluminum, and combinations thereof.

In one embodiment, the substrate comprises a metal nitride such as boron nitride. The boron nitride may be carbon doped. In an exemplary embodiment, the metal nitride may be pyrolitic boron nitride. The metal nitride may include one or more of tantalum, titanium, tungsten, zirconium, hafnium, lanthanum, vanadium, niobium, magnesium, chromium, molybdenum, or beryllium. The metal nitride may include silicon nitride. The metal carbide may include one or more of silicon, tantalum, titanium, tungsten, zirconium, hafnium, lanthanum, vanadium, niobium, magnesium, chromium, molybdenum, or beryllium. The metal boride may may include one or more of silicon, tantalum, titanium, tungsten, zirconium, hafnium, lanthanum, vanadium, niobium, magnesium, chromium, molybdenum, or beryllium. The metal oxide may include one or more of silicon, tantalum, titanium, tungsten, zirconium, hafnium, lanthanum, vanadium, niobium, magnesium, chromium, molybdenum, or beryllium. In one embodiment, the substrate may include one or more of silicon nitride, silicon carbide, or quartz. In one embodiment the substrate may include two or more of the above compounds.

The substrate shape and size may depend on the particular end-use application. The substrate may include a single layer, or may include multiple layers. The multiple layers may be formed from either same material, or from different materials from layer to layer. The different layers, for example, may have differing electrical and thermal properties.

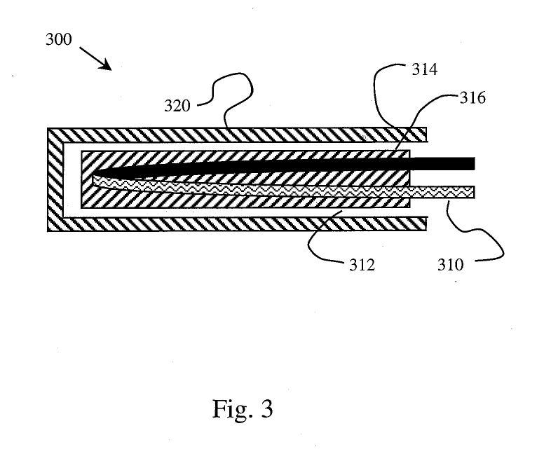

With reference to FIG. 3, an article 300 comprising an embodiment of the invention is shown. The article 300 includes a heating element 310 disposed within a substrate 312. The substrate is sized and shaped to be received within a volume defined by a inner surface of a casing 314 and through an open end. The outer surface 316 of the substrate may contact with, but is not necessarily adhered to, an inner surface of the casing. An outer surface 320 of the casing may be exposed to the harsh environment during use.

The casing is formed from the same materials suitable for use as the coating, above. The thickness of the casing may be substantially thicker than the coating, however, and may provide relatively more barrier volume for etch resistance, as well as more volume for relatively greater mechanical strength. A gap between the casing inner surface and the substrate outer surface may be just large enough to allow the substrate to slide into the casing during assembly. A smaller gap or tighter tolerance may allow for increased thermal transfer.

Thermal interface materials, particularly thermal interface adhesives, may be used in the gap to increase the thermal transfer from the substrate out through the casing. In one embodiment, the thermal interface adhesive is the same, or similar, as the material for use as the coating and/or casing. Further, an axially ridged complementary structure may help mate the substrate and the casing inner surface. The ridges can translate axially past each other to increase the contact surface area for relatively improved thermal transfer.

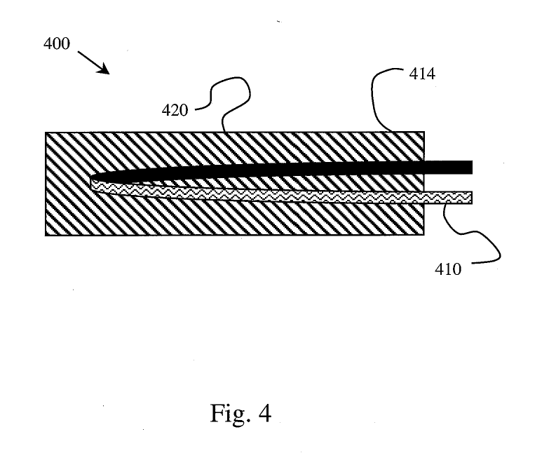

With regard to FIG. 4, an article 400 comprising an embodiment of the invention is shown. The article 400 includes a heating element 410 embedded in a monolith structure 414. The monolith structure has an outward facing surface 420 that may be exposed during use.

The monolith structure is formed from the material suitable for use as the coating and the casing disclosed above. The monolith structure may be used as a heater in one embodiment.

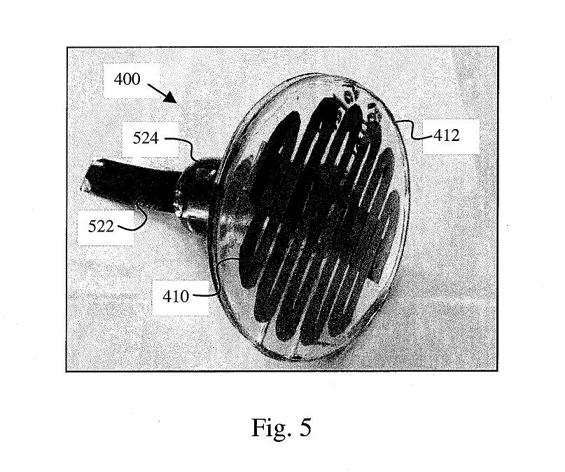

A photograph of a heater comprising the schematic monolith structure of FIG. 4 is shown in FIG. 5. The same reference numbers are used to indicate the corresponding or similar parts from FIG. 4 to FIG. 5. Also visible are heating element leads 522 that extend from a back side of the heater. An extension of the monolith, indicated by 524, covers, supports, and protects the leads from exposure to the harsh environment during use.

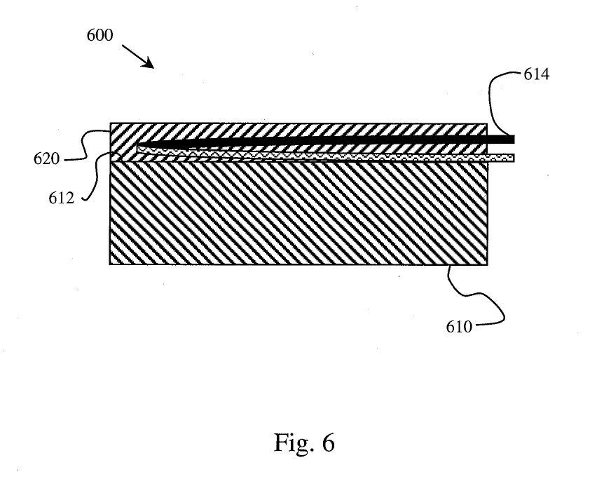

With reference to FIG. 6, an article 600 comprising an embodiment of the invention is shown. The article 600 includes a substrate 610 with a surface 612 upon which a heating element 614 is disposed. Overlaying the heating element on the substrate surface is a coating layer 620. The heating element rests on the substrate surface and is configured to generate thermal energy and direct that energy outward through the coating layer.

In alternative embodiments, a thermal insulating layer or a thermal reflecting layer may be disposed on the substrate surface below the heating element to shield the substrate from generated heat, and to increase the thermal generation efficiency of the heater device. A channel or groove may be cut or etched into the substrate surface and the heating element may be disposed within the groove or channel to provide additional mechanical support for the heating element during use.

In one embodiment, a heater includes a heating element. The heating element includes a plurality of leads and an electrically resistive heat-generating body. A glassy structure sealing the heating element from a proximate environment. The glassy structure includes a material disclosed as being useful for the coating. Particularly, the glassy structure includes yttrium, aluminum, and silicon in proporations and amounts sufficient that the glassy structure resists etching in the harsh environment.

In another embodiment, a chuck includes an electrode and the glassy structure. The glassy structure seals the electrode from a proximate environment. The glassy structure includes yttrium, aluminum, and silicon. And, the glassy structure resists etching in the harsh environment.

### EXAMPLES

The following examples are intended only to illustrate methods and embodiments in accordance with the invention, and as such should not be construed as imposing limitations. Unless specified otherwise, all ingredients are commercially available from such common chemical suppliers as Alpha Aesar, Inc. (Ward Hill, Mass.), Spectrum Chemical Mfg. Corp. (Gardena, Calif.), and the like.

### Example 1

### Preparation and Test

Samples 1-5 are prepared. Samples 1-5 include oxide powders mixed in the proportions set forth in Tables 1-2. The powders are weighed, mixed, and melted at temperatures greater than about 1500 degrees Celsius to achieve a fully molten homogeneous mass. The samples are allowed to cool slowly and then are tested.

TABLE 1
Ingredients for Samples 1–5. Molar % of cations.

| Sample # | Y | Ce | Gd | Al | Si | total |
|---|---|---|---|---|---|---|
| 1 | 28.6 | — | — | 28.6 | 42.9 | 100 |
| 2 | — | — | 28.6 | 28.6 | 42.9 | 100 |
| 3 | 12 | — | — | 40 | 48 | 100 |
| 4 | — | 12 | — | 40 | 48 | 100 |
| 5 | — | — | 12 | 40 | 48 | 100 |

TABLE 2
Weight (g) of oxides used to meet molar ratios.

| Sample # | Y₂O₃ | CeO₂ | Gd₂O₃ | Al₂O₃ | SiO₂ | total |
|---|---|---|---|---|---|---|
| 1 | 20 | — | — | 20 | 60 | 100 |
| 2 | — | — | 20 | 20 | 60 | 100 |
| 3 | 8.1 | — | — | 27 | 64.9 | 100 |
| 4 | — | 15 | — | 25 | 60 | 100 |
| 5 | — | — | 8.1 | 27 | 64.9 | 100 |

* Y = yttrium, Gd = gadolinium, Ce = cerium, Al = aluminum, Si = silicon (cation at %).

The glassy masses that result are cooled and tested. Samples 1-5 are each analyzed by two different tests: thermal mechanical analysis and reactive ion etch test. The samples 1-5 are then further tested for coefficient of thermal expansion values.

Thermal Mechanical Analysis is performed in expansion mode on a TMA Q400 Thermo Mechanical Analyzer from TA Instruments. Experimental parameters were set at: 0.0500 Newtons of force, 5.000 grams static weight, nitrogen purge at 50.0 mu/min, and 0.5 sec/pt sampling interval. The samples are analyzed from ambient to 700 degrees Celsius then cooled to ambient at a 5 degrees Celsius per minute ramp rate for the number of cycles shown on the thermogram.

The reactive ion etch test (RIE test) parameters include NF₃/Ar (16/34 standard cubic centimeter per minute (sccm),) 100 mTorr, 400 W, 100 minutes. The results are listed in Table 2. Comparative Samples C-1 and C-2 are uncoated, untreated, standard silicon dioxide (SiO₂) wafers. The results are listed in Tables 3-4.

TABLE 3
RIE test results of Samples 1–5

gravimetric
Etch rate

| Sample | Å/min | (+/−) |
|---|---|---|
| C-1 | 448.6 | 0.7 |
| C-2 | 451.8 | 0.7 |
| 1 | 2.6 | 0.7 |
| 2 | 0.9 | 0.5 |
| 3 | 0.8 | 0.6 |
| 4 | 7.6 | 0.7 |
| 5 | 1.7 | 0.6 |

TABLE 4
Measured CTE of samples 1–5.

| sample | CTE, ppm/° C. |
|---|---|
| 1 | 5.9 |
| 2 | 6.3 |
| 3 | 4 |
| 4 | 4.3 |
| 5 | 4.3 |

CTE calibration is performed with an aluminum standard at a 5° C./min ramp rate under nitrogen purge. Temperature calibration is performed with an indium standard at a 5° C./min ramp rate under nitrogen purge. Following calibration, the CTE calibration is verified to be within 0.5 ppm/° C. and the temperature calibration is verified to be within 0.5 degrees Celsius of expected values. Each sample was about 10 centimeters in diameter.

Inspection of the samples after testing shows that fluorine was mainly associated with metal fluorides. That is, the halogen interaction formed YF₃ and GdF₃.

### Example 2

### Thermal Shock Tests

Two glass samples were cut and polished from a batch with a cation % composition of 23% Yttrium, 32% aluminum and 45% silicon. The dimensions were 30 mm×10 mm×2 mm and 23 mm×6 mm×2 mm. Three additional samples with dimensions 8 mm×8 mm×9 mm were cut using the same composition.

The two rectangular samples were placed in an alumina boat diameter=50 mm at room temperature, about 25° C. The alumina boat was then set onto ceramic blocks and placed in a preheated air furnace at temperature 800° C. The samples remained in the furnace for 30 minutes and then were removed and placed onto a ceramic block at room temperature. The test was repeated for the other three samples.

The two rectangular samples were ultrasonically inspected in a water tank using a 20 MHz F/4 transducer. Signals were gated to produce an ultrasonic C-scan image. Differences in material properties will reflect incident ultrasound energy. Inclusions will appear at amplitudes higher than “clean” material.

Three of the samples showed no visible changes from the thermal shock. No visible cracks appeared in any of the three blocks. One of the samples cracked after removal from the furnace, but is believed to be a result of a reaction from material on the ceramic boat. The acoustic imaging for the rectangular samples indicates the appearance of inclusions in one sample, but no cracks or inclusions in the other sample. The YAS glass appears to show good thermal shock resistance.

### Example 3

### Additional Material Compositions

Samples 11-20 are prepared by mixing oxide powders at the ratios listed in Table 7. Half of each mixture is then sintered under pressure to form a sintered article, and the other half of each mixture is heated to melting and then poured into a ceramic mold and cooled.

TABLE 7
Ratio of oxides used to meet molar ratios.

| Sample # | Y₂O₃ | CeO₂ | Gd₂O₃ | Al₂O₃ | SiO₂ | total |
|---|---|---|---|---|---|---|
| 11 | 20 | 10 | — | 20 | 50 | 100 |
| 12 | 20 | — | 10 | 20 | 50 | 100 |
| 13 | 10 | 10 | — | 25 | 55 | 100 |
| 14 | 10 | — | 10 | 25 | 55 | 100 |
| 15 | 5 | 10 | 15 | 20 | 50 | 100 |
| 16 | 5 | 15 | 10 | 20 | 50 | 100 |
| 17 | — | 10 | 20 | 20 | 50 | 100 |
| 18 | — | 20 | 10 | 20 | 50 | 100 |
| 19 | — | 15 | — | 25 | 60 | 100 |
| 20 | 45 | — | — | 25 | 35 | 100 |

* Y = yttrium, Gd = gadolinium, Ce = cerium, Al = aluminum, Si = silicon (cation at %).

Each of the samples 11-24 part A (sintered) and part B (molten) are formed into test pucks. Each puck is transparent with little or no visibly noticeable haze. Test pucks 21-24 are exposed to flourine gas (nitrogen trifluoride feedstock) at a temperature of 400 degrees Celsius for 6 hours with a measured gravimetric etch rate of less than 1 A/min.

The embodiments described herein are examples of compositions, structures, systems, and methods having elements corresponding to the elements of the invention recited in the claims. This written description may enable those of ordinary skill in the art to make and use embodiments having alternative elements that likewise correspond to the elements of the invention recited in the claims. The scope of the invention thus includes compositions, structures, systems and methods that do not differ from the literal language of the claims, and further includes other structures, systems and methods with insubstantial differences from the literal language of the claims. While only certain features and embodiments have been illustrated and described herein, many modifications and changes may occur to one of ordinary skill in the relevant art. The appended claims cover all such modifications and changes.

1. A processing apparatus for use in a semiconductor processing chamber, the apparatus comprising:
a base substrate for placing a wafer thereon,
at least one electrode embedded in or disposed on or under the base substrate, the electrode is selected from a resistive heating electrode, a plasma-generating electrode, an electrostatic chuck electrode, and an electron-beam electrode
at least a coating layer disposed on the base substrate, the coating layer comprising a glassy material comprising at least one lanthanide, aluminum and silicon; wherein
the coating layer composition resists etching when the apparatus is exposed to a harsh operating environment at a temperature range of 25-1500° C., the environment is one of an environment comprising halogen, a plasma etching environment, a reactive ion etching environment, a plasma cleaning environment, and a gas cleaning environment.

2. The processing apparatus as defined in claim 1, wherein the coating layer further comprises a glass former.

3. The processing apparatus as defined in claim 2, wherein the glass former comprises at least one of boron, germanium, or phosphorus.

4. The processing apparatus as defined in claim 2, wherein the lanthanide is yttrium, cerium, or gadolinium.

5. The processing apparatus as defined in claim 4, wherein the lanthanide is yttrium.

6. The processing apparatus as defined in claim 1, wherein glassy material comprises at least two lanthanides.

7. The processing apparatus as defined in claim 1, wherein the coating layer comprises 10-30 mol. % Y, Gd, or Ce; 25 to 25 mol. % Al; and 40 to 50 mol % Si.

8. The processing apparatus as defined in claim 7, wherein the coating layer comprises 10-30 mol. % Y; 25 to 25 mol. % Al; and 40 to 50 mol % Si.

9. The processing apparatus as defined in claim 7, further comprising 1 to 15 mol % of at least a glass former M.

10. The processing apparatus as defined in claim 1, wherein the harsh environment comprises fluorine produced with the aid of a plasma.

11. The processing apparatus as defined in claim 1, wherein the harsh environment comprises sulfur hexafluoride (SF₆) or nitrogen trifluoride (NF₃).

12. The processing apparatus as defined in claim 1, wherein the harsh environment is at a temperature in a range of from about 100 degrees Celsius to about 500 degrees Celsius.

13. The processing apparatus as defined in claim 1, wherein the harsh environment is at a temperature in a range of from about 500 degrees Celsius to about 750 degrees Celsius.

14. The processing apparatus as defined in claim 1, wherein the harsh environment is at a temperature in a range of from about 750 degrees Celsius to about 1000 degrees Celsius.

15. The processing apparatus as defined in claim 1, wherein the harsh environment is at a temperature in a range of from about 1000 degrees Celsius to about 1100 degrees Celsius.

16. The processing apparatus as defined in claim 1, wherein the harsh environment is at a temperature in a range of from about 1100 degrees Celsius to about 1250 degrees Celsius.

17. The processing apparatus as defined in claim 1, wherein the harsh environment is at a temperature in a range of from about 1250 degrees Celsius to about 1500 degrees Celsius.

18. The processing apparatus as defined in claim 1, wherein the composition resists etching such that less than 3 Angstroms per minute of material is lost during exposure to NF₃/Ar (16/34 ratio at a flow rate of one standard cubic centimeter per minute (sccm) a pressure of 100 mTorr).

19. The processing apparatus as defined in claim 1, wherein the coating layer composition resists etching such that less than 2 Angstroms per minute of material is lost during exposure to NF₃/Ar (16/34 ratio at a flow rate of one standard cubic centimeter per minute (sccm) a pressure of 100 mTorr).

20. The processing apparatus as defined in claim 1, wherein the coating layer composition resists etching such that less than 1 Angstroms per minute of material is lost during exposure to NF₃/Ar (16/34 ratio at a flow rate of one standard cubic centimeter per minute (sccm) a pressure of 100 mTorr).

21. The processing apparatus as defined in claim 1, wherein the coefficient of thermal expansion of the coating layer composition is in a range of from about 2.0×10⁻⁶ to about 5.2×10⁻⁶.

22. The processing apparatus as defined in claim 1, wherein the coefficient of thermal expansion of the coating layer composition is in a range of from about 5.3×10⁻⁶ to about 6×10⁻⁶.

23. The processing apparatus as defined in claim 1, wherein the coating layer resists thermal shock such that a thermal cycle that includes a temperature change of up to about 1000 degrees Celsius to room temperature at a temperature loss rate that is based on the thermal conductivity of the composition produces no visible cracking or defect.

24. The processing apparatus as defined in claim 23, wherein the thermal cycle is repeatable at least 100 cycles without visible cracking or defect.

25. The processing apparatus as defined in claim 1, wherein the coating layer resists thermal shock such that a thermal cycle that includes a temperature change of up to about 800 degrees Celsius to room temperature at a temperature loss rate that is based on water quenching of the composition produces no visible cracking or defect.

26. The processing apparatus as defined in claim 25, wherein the thermal cycle is repeatable at least 100 cycles without visible cracking or defect.

27. The processing apparatus as defined in claim 1, wherein the base substrate comprises an electrically conducting material selected from the group of graphite, refractory metals, transition metals, rare earth metals and alloys thereof.

28. The processing apparatus as defined in claim 1, wherein the base substrate comprises an electrically insulating material selected from the group of oxides, nitrides, carbides, carbonitrides or oxynitrides of elements selected from a group consisting of B, Al, Si, Ga, Y; a high thermal stability zirconium phosphate having an NZP structure of NaZr₂ (PO₄)₃; refractory hard metals; transition metals; oxide, oxynitride of aluminum, and combinations thereof.

29. The processing apparatus as defined in claim 28, wherein the coating layer has a thickness in a range of from about 5 micrometers to about 100 micrometers.

30. The processing apparatus as defined in claim 28, wherein the coating layer has a thickness in a range of from about 100 micrometers to about 1 millimeter.

31. The processing apparatus as defined in claim 30, wherein the coating layer has a thickness greater than 1 millimeter.

32. The processing apparatus as defined in claim 31, wherein the coating composition is single crystal or quasi-single crystal, or the composition has few or no grain boundaries.

33. The processing apparatus as defined in claim 1, wherein the coating composition is amorphous, and has few or no grain boundaries.

34. A processing apparatus for use in a semiconductor processing chamber, the apparatus comprising:
a base substrate for placing a wafer thereon,
at least one electrode embedded in or disposed on or under the base substrate, the electrode is selected from a resistive heating electrode, a plasma-generating electrode, an electrostatic chuck electrode, and an electron-beam electrode
a casing has an inner surface that defines a volume configured to receive the substrate, the casing comprising a glassy material comprising at least one lanthanide, aluminum and silicon; wherein
the casing resists etching when the apparatus is exposed to a harsh operating environment at a temperature range of 25-1500° C., the environment is one of an environment comprising halogen, a plasma etching environment, a reactive ion etching environment, a plasma cleaning environment, and a gas cleaning environment.

35. The processing apparatus as defined in claim 34, wherein the casing has a wall thickness in a range of from about 1 millimeter to about 100 millimeter.

36. The processing apparatus as defined in claim 34, wherein the casing has a wall that has an inner surface that is ridged to increase a contact surface area with a mating surface of the substrate.

37. The processing apparatus as defined in claim 34, wherein the electrode is a resistive heating electrode, and whether the apparatus further comprising a plurality of leads to provide electrical communication therewith.

38. The processing apparatus as defined in claim 34, wherein the casing further comprises a glass former.

39. The processing apparatus as defined in claim 38, wherein the glass former comprises at least one of boron, germanium, or phosphorus.

40. The processing apparatus as defined in claim 34, wherein the lanthanide is yttrium, cerium, or gadolinium.

41. The processing apparatus as defined in claim 40, wherein the lanthanide is yttrium.

42. The processing apparatus as defined in claim 34, wherein glassy material comprises at least two lanthanides.

43. The processing apparatus as defined in claim 34, wherein the casing comprises 10-30 mol. % Y, Gd, or Ce; 25 to 25 mol. % Al; and 40 to 50 mol % Si.

44. The processing apparatus as defined in claim 43, wherein the casing comprises 10-30 mol. % Y; 25 to 25 mol. % Al; and 40 to 50 mol % Si.

45. The processing apparatus as defined in claim 44, wherein the casing further comprising 1 to 15 mol % of at least a glass former M.

46. A method for producing a wafer processing apparatus, comprising the steps of:
providing a base substrate comprising at least one of a nitride, carbide, carbonitride or oxynitride of elements selected from a group consisting of B, Al, Si, Ga, refractory hard metals, transition metals, and combinations thereof;
depositing a film electrode onto the base substrate, the film electrode has a CTE ranging from 0.75 to 1.25 of the base substrate layer;
coating the base substrate and the film electrode with a protective layer, wherein the protective layer is formed by contacting powders comprising at least one of yttrium, cerium, or gadolinium; and aluminum and silicon; and heating the powders to form the glassy protective structure or glassy protective layer.

47. The method as defined in claim 46, wherein the glassy protective layer is formed as a casing or a monolith structure.

48. The method as defined in claim 46, further comprising contacting the glassy protective structure or glassy protective layer to a harsh environment, whereby the glassy protective structure or glassy protective layer resists etching.

49. The method as defined in claim 46, wherein the powders are oxide powders.

50. The method as defined in claim 46, wherein the powders comprising yttrium, aluminum, and silicon, and the glassy structure or glassy layer is a YAS glass.

51. The method as defined in claim 46, wherein the powders comprising the glassy protective structure or glassy protective layer are mixed at a weight ratio of about 45 wt % yttrium oxide, about 20 wt % aluminum oxide, and about 35 wt % silicon dioxide.
